(19) United States
(12) Patent Application Publication
(10) Pub. No.: US 2004/0119121 A1
(43) Pub. Date: Jun. 24, 2004

(54) Semiconductor device and method of manufacturing the same

(76) Inventor: Hironobu Kariyazono, Sakata-shi (JP)

Correspondence Address: EDWARDS & ANGELL, LLP, P.O. BOX 55874, BOSTON, MA, 02205, US

(21) Appl. No.: 10/672,728

(22) Filed: Sep. 26, 2003

(30) Foreign Application Priority Data
Sep. 26, 2002 (JP) 2002-281080

(51) Int. Cl. H01L 23/62

(52) U.S. Cl. 257/379; 257/359; 257/358

(57) ABSTRACT

A semiconductor device including a resistive conductive layer and a method of manufacturing the semiconductor device.

A method of manufacturing a semiconductor device in which a resistive conductive layer and an MOS transistor are provided on the same semiconductor layer in a mixed manner. The method comprises the steps of forming a resistive conductive layer on the first insulating layer in a formation region for the resistive conductive layer; forming a protective layer so as to cover the resistive conductive layer; and forming a gate insulating layer and a gate electrode in a formation region for the MOS transistor.

### BACKGROUND OF THE INVENTION

1. Field of the Invention

The present invention relates to a novel semiconductor device including a resistive conductive layer and a method of manufacturing the semiconductor device.

2. Description of Related Art

A resistive conductive layer comprising a polysilicon layer, for example, is used as a resistive element formed on a semiconductor layer (for example, see Japanese Published Patent Application 61-242058). In recent years, there is an increasing demand to partially combine the process of manufacturing the resistive element and that of manufacturing a transistor including a Metal Oxide Semiconductor (MOS) structure (hereinafter referred to as ‘MOS transistor’) in order to simplify the manufacturing process and to form the resistive element and the transistor efficiently on the same semiconductor layer.

### SUMMARY OF THE INVENTION

This invention intends to provide a method of manufacturing a semiconductor device, the method capable of manufacturing a resistive element and an MOS transistor efficiently on the same semiconductor layer.

Also, the invention provides a semiconductor device in which a resistive element and an MOS transistor are formed on the same semiconductor layer.

A first method of manufacturing a semiconductor device of the present invention is for forming a semiconductor device in which a resistive conductive layer and an MOS transistor are provided on the same semiconductor layer in a mixed manner, the method comprising:

forming a first insulating layer over the semiconductor layer in a formation region for the resistive conductive layer;

forming an elements isolation region in a formation region for the MOS transistor;

forming the resistive conductive layer on the first insulating layer in the formation region for the resistive conductive layer;

forming a protective layer so as to cover the resistive conductive layer in the formation region for the resistive conductive layer;

forming a second insulating layer on the semiconductor layer by exposing a surface of the semiconductor layer and thermally oxidizing the surface of the semiconductor layer in the formation region for the MOS transistor;

forming a gate conductive layer at least on the second insulating layer; and

forming a gate electrode and a gate insulating layer by patterning the gate conductive layer and the second insulating layer in the formation region for the MOS transistor.

The resistive conductive layer refers to a conductive layer that is formed on the semiconductor layer and functions as a resistive element.

According to the first method of manufacturing a semiconductor device of the invention, the resistive conductive layer can be prevented from getting oxidized by conducting the thermal oxidization on the surface of the semiconductor layer under a state that the protective layer covers the resistive conductive layer when forming the second insulating layer. Consequently, the resistive conductive layer can be formed with a desired resistance value. The above advantages will be recited in the description of embodiments of the invention.

In that case, the semiconductor layer may comprise a layer including a silicon substrate on the surface thereof, the first and the second insulating layers each may comprise a silicon oxide layer, and the protective layer may comprise a silicon nitride layer or a silicon oxynitride layer.

The second method of manufacturing a semiconductor device of the invention is for forming a semiconductor device in which a resistive conductive layer and an MOS transistor are provided on a same semiconductor layer in an mixed manner, the method comprising:

forming a first insulating layer over the semiconductor layer in a formation region for the resistive conductive layer;

forming an elements isolation region in a formation region for the MOS transistor;

forming the resistive conductive layer on the first insulating layer in the formation region for the resistive conductive layer;

forming a protective layer on the resistive conductive layer in the formation region for the resistive conductive layer;

forming a second insulating layer on the semiconductor layer by exposing a surface of the semiconductor layer and thermally oxidizing the surface of the semiconductor layer in the formation region for the MOS transistor;

forming a third insulating layer on a side surface of the resistive conductive layer;

forming a gate conductive layer at least on the second insulating layer; and

forming a gate electrode and a gate insulating layer by patterning the gate conductive layer and the second insulating layer in the formation region for the MOS transistor.

According to the second method of manufacturing a semiconductor device of the invention, the resistive conductive layer can be prevented from getting oxidized by conducting thermal oxidization on the surface of the semiconductor layer under a state that the protective layer is formed on the resistive conductive layer when forming the second insulating layer. Consequently, the resistive conductive layer with a desired resistance value can be formed.

The semiconductor layer may comprise a layer including a silicon layer on the surface thereof, the first, the second and the third insulating layers each may comprise a silicon oxide layer, and the protective layer may comprise a silicon nitride layer or a silicon oxynitride layer.

Also, the second insulating layer and the third insulating layer can be formed in the same step. Furthermore, each of the second insulating layer and the third insulating layer is formed by oxidizing the surface of the semiconductor layer and the side surface of the resistive conductive layer.

Moreover, the first and the second methods of manufacturing a semiconductor device of the invention may adopt the following modes (1) to (5).

(1) The gate conductive layer may comprise a multi-layered structure including a polysilicon layer and a metal layer. The resistance of the gate electrode is thereby reduced, so that delay of a gate wiring can be improved.

(2) The resistive conductive layer comprises a polysilicon layer.

(3) The first insulating layer and the elements isolation region can be formed in the same step, thereby enhancing efficiency of the manufacturing process. In that case, the first insulating layer and the elements isolation region can be formed by oxidizing the surface of the semiconductor layer.

(4) The method of manufacturing a semiconductor device is for manufacturing a semiconductor device in which the resistive conductive layer, and a high breakdown voltage transistor and a low breakdown voltage transistor of insulated gate types are formed on the same semiconductor layer, the high breakdown voltage transistor including proof voltage between a source and a drain, which is different from that of the low breakdown voltage transistor. Moreover, the MOS transistor comprises the high breakdown voltage transistor.

The high breakdown voltage transistor is usually formed with a gate-insulating layer having a large thickness so as to withstand a high voltage. When the surface of the semiconductor layer is thermally oxidized with the resistive conductive layer exposed to the outside in an attempt to form a gate insulating layer with a large thickness, the resistive conductive layer is oxidized to a great extent. Therefore, using the method of manufacturing, a semiconductor device of the invention derives a great advantage from preventing oxidization of the resistive conductive layer.

(5) The second insulating layer is formed by exposing at least a region of the semiconductor layer on which the gate electrode is formed to the outside and then thermally oxidizing the surface in the formation region for the MOS transistor.

A semiconductor device of the invention comprises:

a semiconductor layer;

a MOS transistor formed on the semiconductor layer; and

a resistive conductive layer formed on the semiconductor layer through an insulating layer, wherein;

the MOS transistor comprises a gate insulating layer and a gate electrode formed on the gate insulating layer.

The first and the second methods of manufacturing a semiconductor device of the invention may adopt the following modes (1) to (6).

(1) The gate electrode comprises a multi-layered structure including a polysilicon layer and a metal layer.

(2) The resistive conductive layer comprises a polysilicon layer.

(3) The semiconductor layer may comprise a layer including a silicon layer at least on the surface thereof, and the gate insulating layer may comprise a silicon oxide layer.

(4) The semiconductor device may comprise a high breakdown voltage transistor and a low breakdown voltage transistor of insulated gate types formed on the semiconductor layer, the high breakdown voltage transistor including a proof voltage between a source and a drain, which is different from that of the low breakdown voltage transistor. Furthermore, the MOS transistor may comprise the high breakdown voltage transistor.

(5) Moreover, the semiconductor device may comprise a protective layer so as to cover the resistive conductive layer.

(6) In addition, the semiconductor device may comprise a protective layer formed on the resistive conductive layer.

### BRIEF DESCRIPTION OF DRAWINGS

FIG. 1 is a plan view schematically showing a semiconductor device according to the first embodiment to which the present invention is applied.

FIG. 2 is a plan view schematically showing a resistive conductive layer shown in FIG. 1.

FIG. 3 is a sectional view schematically showing a semiconductor device using an MOS transistor shown in FIG. 1 as a high breakdown voltage transistor.

FIG. 4 is a sectional view schematically showing one step of a method of manufacturing the semiconductor device shown in FIG. 1.

FIG. 5 is a sectional view schematically showing one step of the method of manufacturing the semiconductor device shown in FIG. 1.

FIG. 6 is a sectional view schematically showing one step of the method of manufacturing the semiconductor device shown in FIG. 1.

FIG. 7 is a sectional view schematically showing one step of the method of manufacturing the semiconductor device shown in FIG. 1.

FIG. 8 is a sectional view schematically showing one step of the method of manufacturing the semiconductor device shown in FIG. 1.

FIG. 9 is a sectional view schematically showing one step of the method of manufacturing the semiconductor device shown in FIG. 1.

FIG. 10 is a sectional view schematically showing one step of the method of manufacturing the semiconductor device shown in FIG. 1.

FIG. 11 is a sectional view schematically showing one step of the method of manufacturing the semiconductor device shown in FIG. 1.

FIG. 12 is a sectional view schematically showing one step of the method of manufacturing the semiconductor device shown in FIG. 1.

FIG. 13 is a plan view schematically showing a semiconductor device according to the second embodiment to which the invention is applied.

FIG. 14 is a sectional view schematically showing one step of a method of manufacturing the semiconductor device shown in FIG. 13.

FIG. 15 is a sectional view schematically showing one step of the method of manufacturing the semiconductor device shown in FIG. 13.

FIG. 16 is a sectional view schematically showing one step of the method of manufacturing the semiconductor device shown in FIG. 13.

FIG. 17 is a sectional view schematically showing one step of the method of manufacturing the semiconductor device shown in FIG. 13.

FIG. 18 is a sectional view schematically showing one step of the method of manufacturing the semiconductor device shown in FIG. 13.

### DETAILED DESCRIPTION OF THE INVENTION

Preferred embodiments of the invention will be explained below with reference to accompanying drawings.

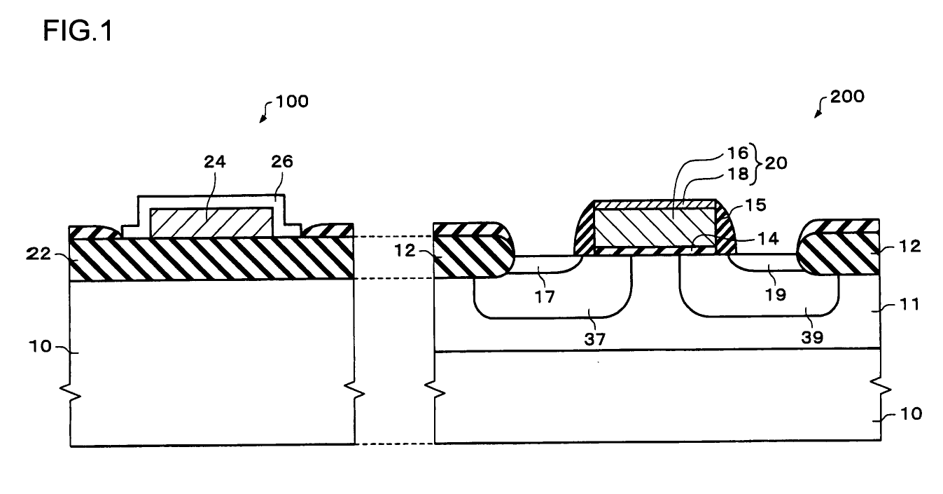

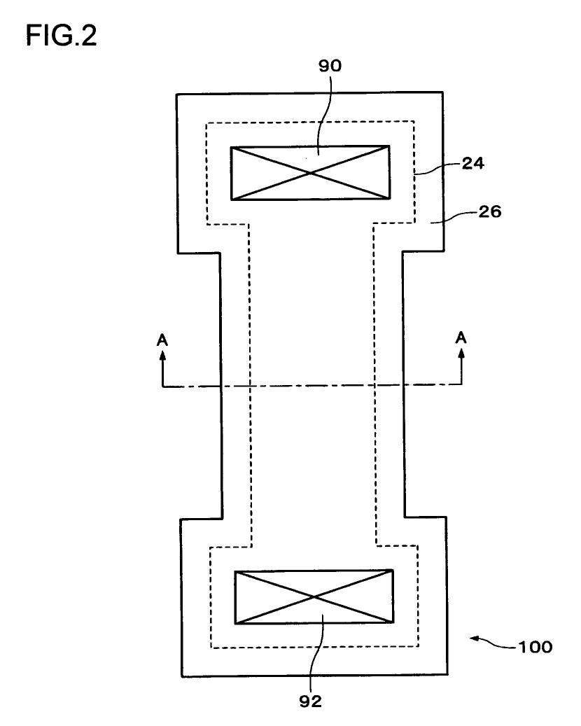

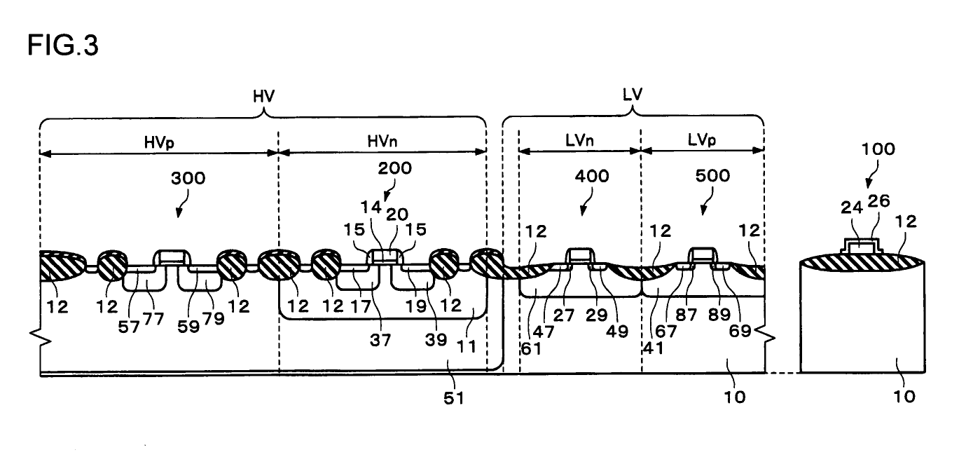

FIG. 1 is a sectional view schematically showing a semiconductor device according to the first embodiment to which the invention is applied. FIG. 2 is a plan view schematically showing a resistive conductive layer 24 shown in FIG. 1. FIG. 3 is a sectional view schematically showing a semiconductor device using an MOS transistor 200 shown in FIG. 1 as a high breakdown voltage transistor. Here, FIG. 1 shows a section along a line 1-1′ in FIG. 2.

The semiconductor device of this embodiment comprises a resistive element 100 and the MOS transistor 200 as shown in FIG. 1. The resistive element 100 and the MOS transistor 200 are on the same semiconductor layer in a mixed manner. Here, in the semiconductor device of this embodiment, a semiconductor substrate 10 comprising a p-type silicon substrate is employed as the semiconductor layer. Furthermore, a gate electrode 20 of the MOS transistor 200 comprises a multi-layered structure including a doped polysilicon layer 16 and a metal layer 18. This type of structure is also usually called a MOS structure.

The resistive element 100 comprises the resistive conductive layer 24 as shown in FIG. 1. This resistive conductive layer 24 is arranged on a first insulating layer 22 formed on the semiconductor substrate 10 and comprises a doped polysilicon. Furthermore, a protective layer 26 is formed on the resistive element 100 so as to cover the resistive conductive layer 24 and comprises a silicon nitride film or a silicon oxynitride film, for example.

In addition, the resistive conductive layer 24 comprises impurities doped therein. The resistance value of the resistive conductive layer 24 can be set to a desired value by appropriately adjusting the kind and the amount of a impurity to be doped into the layer. A P-type or n-type impurity can be doped into the resistive conductive layer 24.

As shown in FIG. 2, contacts 90 and 92 are formed on the resistive conductive layer 24, and each of these contacts 90 and 92 is connected to a wiring layer (not shown in the drawing). The resistive conductive layer 24 is thereby electrically connected to the wiring layer through each of the contacts 90 and 92.

As shown in FIG. 1, the MOS transistor 200 comprises a gate insulating layer 14 and the gate electrode 20, and the gate electrode 20 is formed on the gate-insulating layer 14. In this embodiment, the gate-insulating layer 14 comprises a silicon oxide layer, and the gate electrode 20 comprises the polysilicon layer 16 and the metal layer 18. In other words, the gate electrode 20 comprises a polycide structure. This reduces resistance of the gate electrode and reduces the delay of a gate wiring. The polysilicon layer 16 comprises doped polysilicon. Moreover, a metal to be used for the metal layer 18 includes tungsten and molybdenum, for example.

The MOS transistor 200 furthermore comprises an n-type source region 17 and an n-type drain region 19. These source and drain regions 17 and 19 are formed so as to sandwich the gate electrode 20. The source and drain regions 17 and 19 are formed in offset regions 37 and 39, respectively. In addition, a silicide layer may be formed as necessary on each of the source and drain regions 17 and 19.

In the semiconductor device of this embodiment, the MOS transistor 200 is formed in a p-type well 11. In this p-type well 11, the offset regions 37 and 39 are formed, and in these offset regions 37 and 39, the source and drain regions 17 and 19 are formed, respectively.

This semiconductor deice comprises a triple-well structure as shown in FIG. 3. More specifically, in a region HV, an n-type well 51 is formed in the semiconductor substrate 10 comprising the p-type silicon substrate, and in this n-type well 51, a p-type well 11 is formed. Furthermore, as shown in FIG. 3, an n-type well 41 and a p-type well 61 are formed in the semiconductor substrate 10.

In the semiconductor device of this embodiment, as shown in FIG. 3, a high breakdown voltage transistor and a low breakdown voltage transistor are formed along with the resistive element 100 on the same semiconductor substrate 10, and the MOS transistor 200 functions as the high breakdown voltage transistor.

Therefore, as shown in FIG. 3, in the semiconductor device of this embodiment, the high breakdown voltage transistor and the low breakdown voltage transistor are provided along with the resistive element 100 on the same semiconductor substrate 10 in a mixed manner. The resistive element 100 and the MOS transistor 200 shown in FIG. 1 are views partially taken out from the semiconductor device shown in FIG. 3.

In FIG. 3, the region HV indicates a region where the high breakdown voltage transistor is formed while a region LV indicates a region where the low breakdown voltage transistor is formed. Moreover, a region HVp indicates a formation region for a high breakdown voltage P-channel MOS (pMOS) transistor 300 while a region HVn indicates a formation region for a high breakdown voltage N-channel MOS (nMOS) transistor 200. Likewise, a region LVp indicates a formation region for a low breakdown voltage P-channel MOS (pMOS) transistor 500 while a region LVn indicates a formation region for a low breakdown voltage N-channel MOS (nMOS) transistor 400. Each of the transistors is isolated from another with an elements isolation region 12 resulting from LOCOS oxidization. The elements isolation region 12 can be formed in the same step as that of forming the first insulating layer 22, which separates the resistive conductive layer 24 from the semiconductor substrate 10 of the resistive element 100.

Moreover, in this semiconductor device, as shown in FIG. 3, the thickness of the gate insulating layer in each of the high breakdown voltage transistors 200 and 300 is formed to be greater than that of the gate insulating layer in each of the low breakdown voltage transistors 400 and 500.

Here, as shown in FIG. 3, this embodiment illustrates a case that the MOS transistor 200 comprises the triple-well structure; however, the MOS transistor 200 may comprise a twin-well structure. In that case, the n-well 51 and the p-well 11 are formed to be adjacent to each other instead of forming the p-well 11 in the n-well 51.

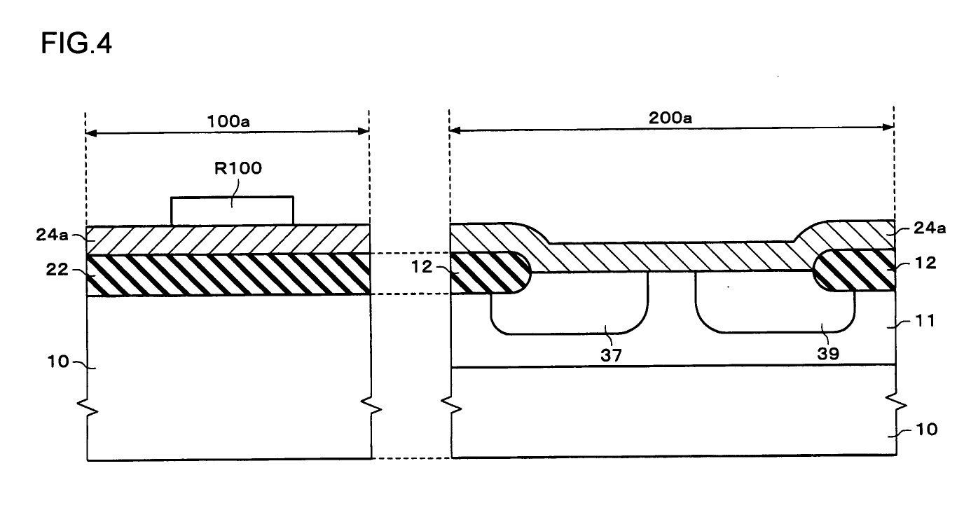

Next, a method of manufacturing a semiconductor device according to the present embodiment will be illustrated with reference to FIG. 4 to FIG. 12. Here, each of the sections of FIG. 4 through FIG. 12 corresponds to the section of the semiconductor device shown in FIG. 1. This embodiment mainly explains a method of manufacturing the resistive element 100 and the high breakdown voltage nMOS transistor 200 of the semiconductor device shown in FIG. 3, and explanation is omitted for the other portions. Hereafter, a region in which to form the resistive element 100 is referred to as ‘a formation region for a resistive element 100a’ while a region in which to form the MOS transistor 200 is referred to as ‘a formation region for an MOS transistor 200a.’

First, the elements isolation region 12 and the first insulating layer 22 are formed on the surface of the semiconductor substrate 10 (see FIG. 3 and FIG. 4). This embodiment illustrates a case of forming the elements isolation region 12 and the first insulating layer 22 in the same step.

More concretely, the surface of the semiconductor substrate 10 is field—oxidized by a LOCOS method, so that the elements isolation region 12 is formed on the semiconductor substrate 10 in the formation region for an MOS transistor 200a while the first insulating layer 22 is formed on the semiconductor substrate 10 in the formation region for a resistive element 100a.

Next, the wells for the high breakdown voltage transistors are formed (see FIG. 3).

More specifically, impurities are doped into a predetermined region by using a resist mask (not shown in the figure) formed by an ordinary photolithographic method, thereby forming the n-type well (n-well) 51 for forming the high breakdown voltage pMOS transistor in the region HV and forming the p-type well (p-well) 11 for forming the high breakdown voltage nMOS transistor in the region HVn (See FIG. 3).

Then, the offset regions 37 and 39 for the source and drain of the high breakdown voltage transistor 200 are formed (See FIG. 3 and FIG. 4). More specifically, the source and drain in the offset regions 37 and 39 are formed by doping n-type impurities onto predetermined regions in the region HVn.

Next, a channel region for the high breakdown voltage transistor 200 is formed. More specifically, a n-type impurity is doped into the channel region in order to adjust a threshold voltage of the high breakdown voltage transistor 200.

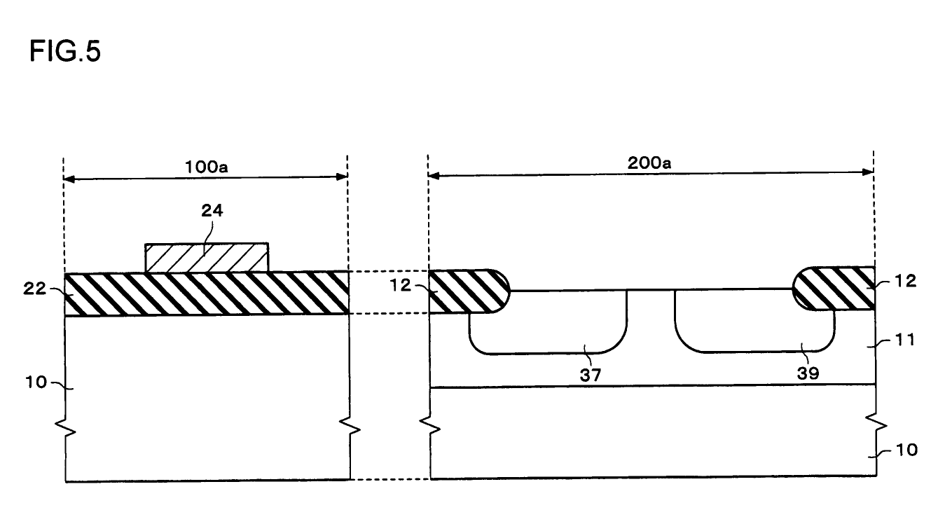

Subsequently, the resistive conductive layer 24 is formed in the formation region for a resistive element 100a (See FIG. 5).

More specifically, a conductive layer 24a for forming the resistive conductive layer 24 is deposited over the entire surface as shown in FIG. 4. This conductive layer 24a comprises polysilicon, for example. Subsequently, an impurity is doped at least into a region of the conductive layer 24a on which to form the resistive conductive layer 24. Doping the impurity adjusts the resistance value of the resistive conductive layer 24 to be a predetermined value.

Next, a resist layer R100 is formed in the formation region for a resistive element 100a, as shown in FIG. 4. This resist layer R100 is formed on the region where the resistive conductive layer 24 is formed. Then, the conductive layer 24a is etched using the resist layer R100 as a mask, so that the resistive conductive layer 24 is formed in the formation region for a resistive element 100a as shown in FIG. 5. This resistive conductive layer 24 is formed into a predetermined planar shape (See FIG. 2). Therefore, the planar shape of the resistive conductive layer 24 is not limited to the shape shown in FIG. 2 and can be any arbitrary shape. Also, in this step, the conductive layer 24a formed in the formation region for an MOS transistor 200a is removed.

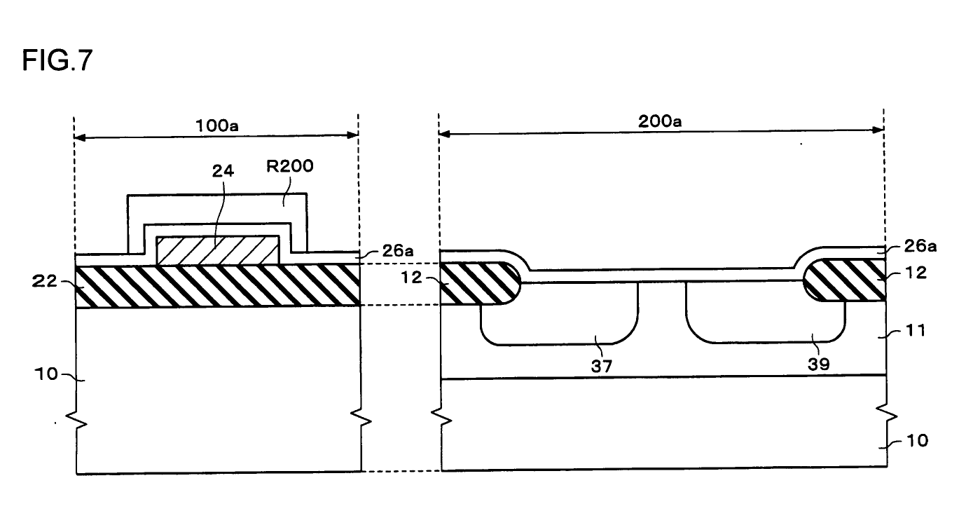

Next, the protective layer 26 is formed on the resistive conductive layer 24 in the formation region for a resistive element 100a (See FIG. 7).

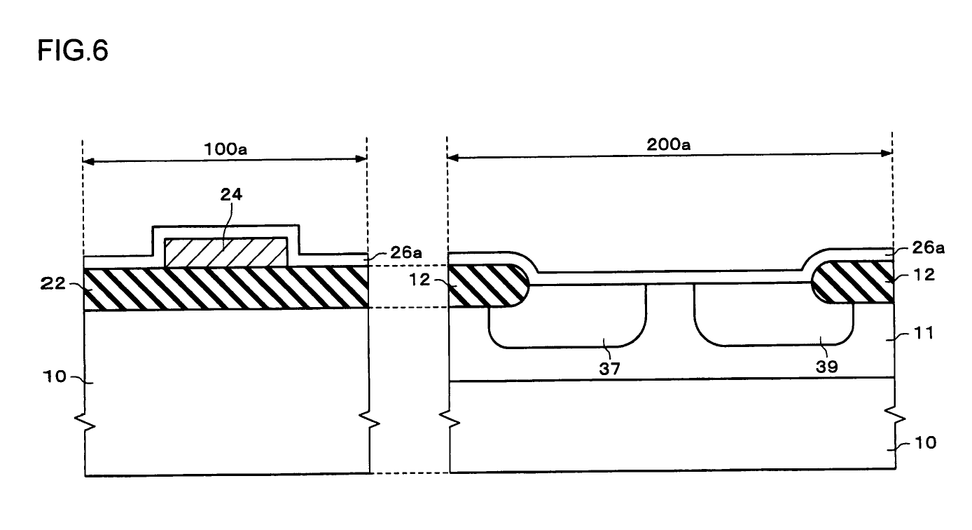

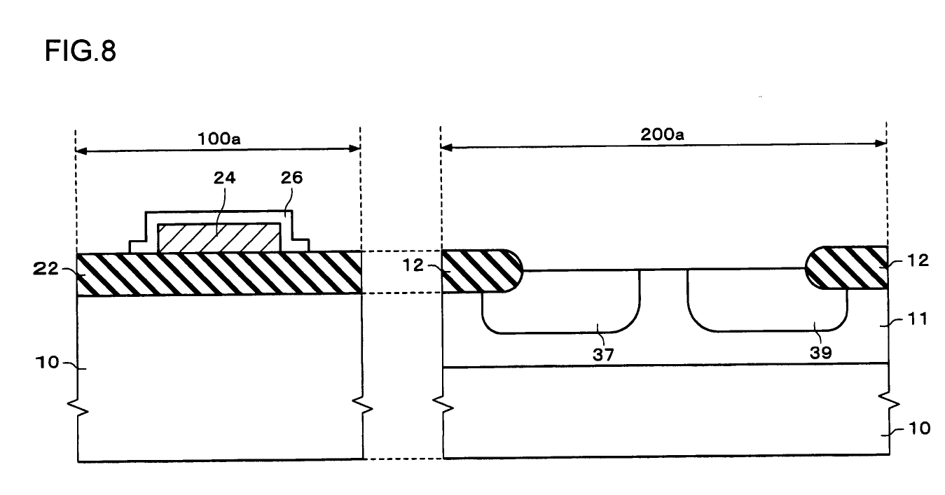

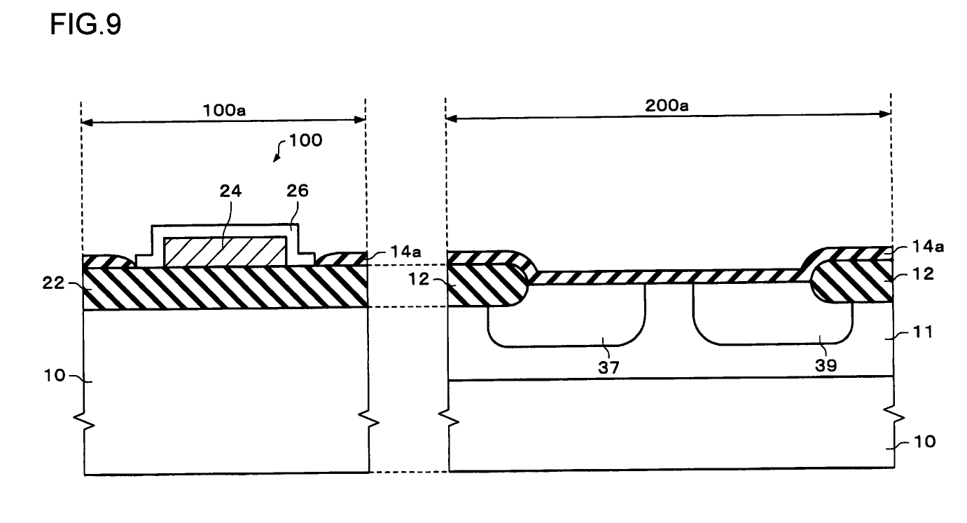

More specifically, after forming a protective layer 26a on the entire surface as shown in FIG. 6, a resist layer R200 is formed in the formation region for a resistive element 100a as shown in FIG. 7. This resist layer R200 is formed so as to cover at least the resistive conductive layer 24. Then, the protective layer 26a is etched using the resist layer R200 as a mask. As shown in FIG. 8, the protective layer 26 is thereby formed in the formation region for a resistive element 100a so as to cover the resistive conductive layer 24. Throughout all the above steps, the resistive element 100 is formed (see FIG. 9). The contacts 90 and 92 are formed on the resistive element 100 in a latter step (see FIG. 2). Also, in this step, the protective layer 26a formed in the formation region for an MOS transistor 200a is removed.

Subsequently, a second insulating layer 14a is formed on the semiconductor substrate 10 in the formation region for an MOS transistor 200a (see FIG. 9).

More specifically, thermal oxidization oxidizes the surface of the semiconductor substrate 10, thereby forming the second insulating layer 14a comprising silicon oxide on the entire surface of the semiconductor substrate 10.

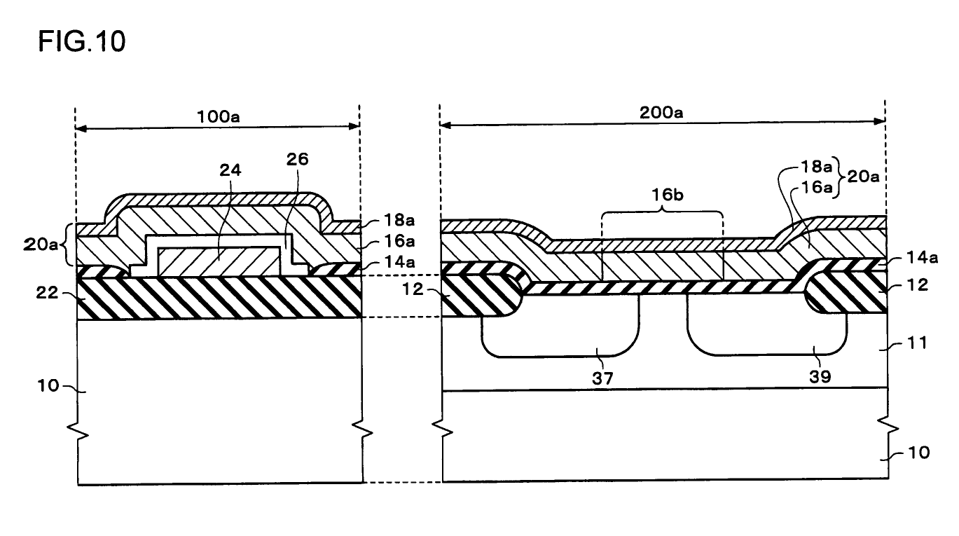

Next, a gate conductive layer 20a for forming the gate electrode 20 is formed on the second insulating layer 14a. (See FIG. 10)

The gate conductive layer 20a comprises double layers of a polysilicon layer 16a and a metal layer 18a. More specifically, after the polysilicon layer 16a is formed on the second insulating layer 14a, the metal layer 18a is deposited on the polysilicon layer 16a, thereby forming the gate conductive layer 20a. The metal layer 18a comprises a metal such as tungsten and molybdenum.

Since polysilicon is a polycrystalline semiconductor, the resistivity thereof is higher than metal. Therefore, when forming the gate electrode 20 comprising the polysilicon layer 16 as with the MOS transistor 200, an impurity corresponding to a channel (n-type impurities in this case) is doped at least into a region (a region 16b in FIG. 10) of the polysilicon layer 16a on which to form the gate electrode 20 before the metal layer 18a is formed. Consequently, the resistance of the polysilicon layer 16a is preliminarily lowered.

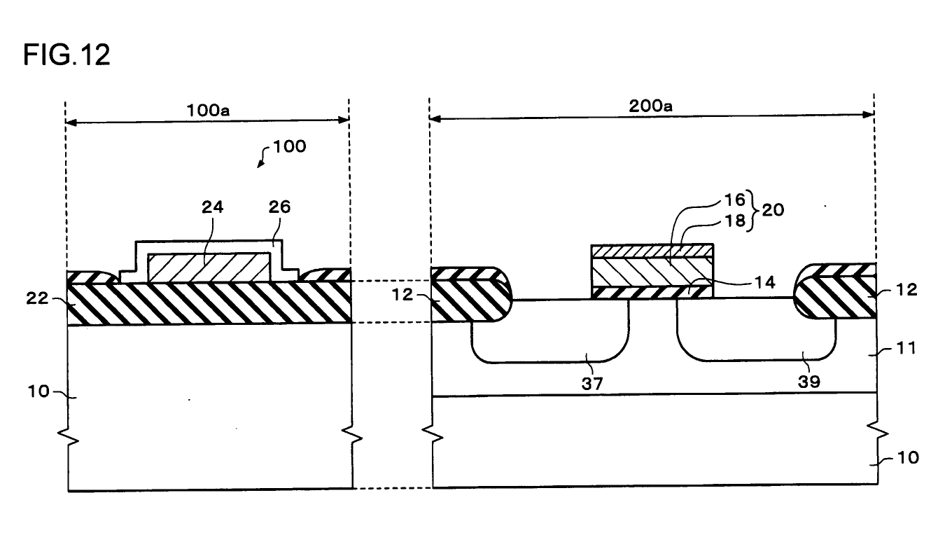

(G) Next, the gate insulating layer 14 and the gate electrode 20 are formed in the formation region for a MOS transistor 200a (see FIG. 12).

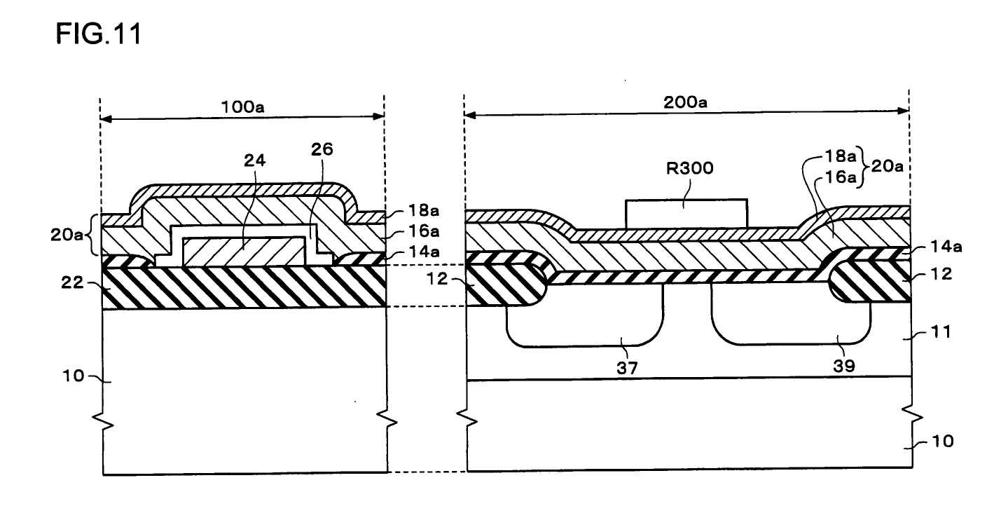

First, a resist layer R300 is formed on the gate conductive layer 20a (see FIG. 11). This resist layer R300 is formed in a region where the gate electrode 20 is formed. Using this resist layer R300 as a mask, the gate conductive layer 20a is etched. A method for etching includes dry etching, for example. As shown in FIG. 12, the gate insulating layer 14 and the gate electrode 20 are thereby formed on the semiconductor substrate 10 in the formation region for an MOS transistor 200a. Also, in this step, the second insulating layer 14a and the gate conductive layer 20a formed over the resistive conductive layer 24 in the formation region for a resistive element 100a are removed.

(H) Subsequently, a side-wall insulating layer 15 is formed on a side surface of the gate electrode 20 in the formation region for an MOS transistor 200a (see FIG. 1). More specifically, the side-wall insulating layer 15 is provided on each side surface of the gate electrode 20 and functions as a mask for forming the source and drain regions 17 and 19. The side-wall insulating layer 15 can be formed by anisotropic-etching such as reactive ion etching (RIE), for example.

Then, the source and drain regions 17 and 19 are formed in the offset regions 37 and 39, respectively, formed in the semiconductor substrate 10 in the formation region for an MOS transistor 200a. These source and drain regions 17 and 19 are formed in a self-aligning manner with the side-wall insulating layers 15 functioning as masks. Throughout all the above steps, the MOS transistor 200 is formed (see FIG. 1).

The semiconductor device and the manufacturing method therefore according to this embodiment exhibit the following advantages.

First, the second insulating layer 14a for forming the gate insulating layer 14 is formed by thermal oxidization in the step (E) after forming the protective layer 26 on the resistive conductive layer 24 in the step (D), so that oxidization of the resistive conductive layer 24 comprising a polysilicon layer is prevented when the second insulating layer 14a is formed with thermal oxidization. Consequently, a desired resistance value can be set for the resistive conductive layer 24. Particularly, a great advantage can be achieved by forming a transistor with a gate insulating layer having relatively a large thickness. The reason for that is explained below.

In the semiconductor device of this embodiment, the gate insulating layer 14 of the MOS transistor 200 is formed by thermally oxidizing the surface of the semiconductor substrate 10. Thus, if the semiconductor substrate 10 is thermally oxidized with the resistive conductive layer 24 exposed, thermal oxidization oxidizes the resistive conductive layer 24, so that the resistive conductive layer 24 may not sufficiently function as the resistive element.

In contrast, according to this embodiment, thermal oxidization is performed with the protective layer 26 covering the resistive conductive layer 24, thereby preventing oxidization of the resistive conductive layer 24. Especially, if the semiconductor substrate 10 is thermally oxidized with the resistive conductive layer 24 exposed to the outside when forming the gate insulating layer 14 with a large thickness, the resistive conductive layer 24 is greatly oxidized. For this reason, using the above method derives a great advantage from preventing oxidization of the resistive conductive layer 24.

For example, a high breakdown voltage transistor usually comprises a gate-insulating layer with a large thickness in order to bear a high voltage. In the semiconductor device of this embodiment, the MOS transistor 200 functions as a high breakdown voltage transistor, so that using the above method yields a great advantage.

Secondly, the resistive element 100 is configured, and the resistive conductive layer 24 comprising a polysilicon layer and the polysilicon layer 16 forming the gate electrode 20 of the MOS transistor 200 are formed in separate steps, so that these are formed with properties suitable for their functions, respectively.

The resistive conductive layer 24 is used as a resistive element. At the same time, the resistance of the gate electrode of the MOS transistor is desirably lowered, and the resistance of the polysilicon layer 16 for the gate electrode 20 of the MOS transistor 200 is preferably lowered. Therefore, opposite properties are desired for the resistive conductive layer 24 and the polysilicon layer 16. Thus, forming these layers in separate steps allows each of them to have its desired property.

Particularly in this embodiment, further reduction in a resistance is intended in order for the gate electrode 20 to comprise a polycide structure. Consequently, a great advantage can be achieved from forming the resistive conductive layer 24 comprising a polysilicon layer and the polysilicon layer 16 in different steps.

Thirdly, after forming the gate conductive layer 20a including the polysilicon layer 16a in step (F) and step (G) subsequent to forming the protective layer 26 on the resistive conductive layer 24 comprising polysilicon in step (D), the polysilicon layer 16a is etched. In this case, the protective layer 26 functions as a stopper layer. In other words, with this protective layer 26, it is possible to prevent the resistive conductive layer 24 comprising polysilicon from getting etched when the polysilicon layer 16a is etched.

Fourth, before forming the gate insulating layer 14 and the gate electrode 20 of the MOS transistor 200, the resistive element 100 is formed. Consequently, the resistive element 100 can be formed without being restricted by the manufacturing process of forming the gate insulating layer 14 and the gate electrode 20 of the MOS transistor 200.

1. The following describes a semiconductor device and a method of manufacturing the same according to the second embodiment of the invention. Here, in the semiconductor device of the second embodiment, elements with the same configuration and function as those of the counterparts in the semiconductor device of the first embodiment are denoted with the same numbers, and a detailed explanation thereof is omitted.

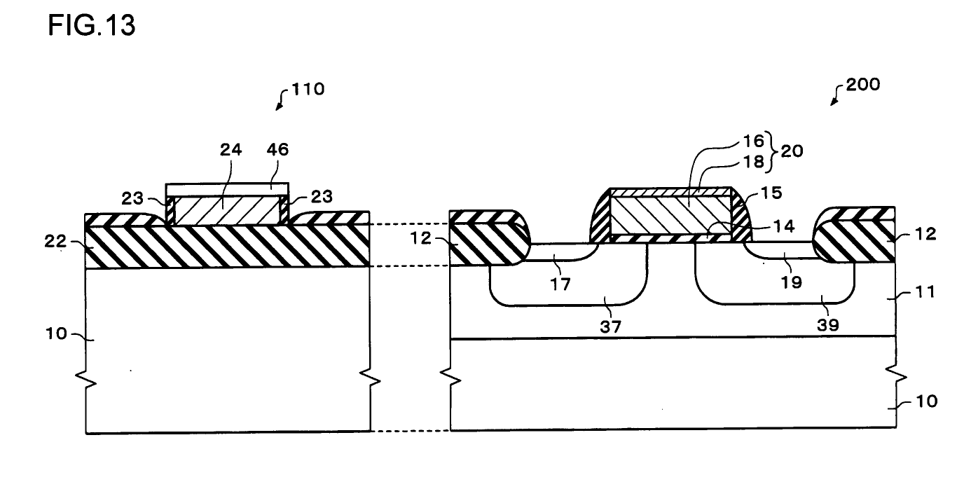

FIG. 13 is a sectional view schematically showing the semiconductor device according to the second embodiment to which the invention is applied.

As shown in FIG. 13, the semiconductor device of the embodiment comprises a resistive element 110 and the MOS transistor 200. The MOS transistor 200 shown in FIG. 13 comprises the same structure as that of the MOS transistor 200 according to the first embodiment and functions as a high breakdown voltage transistor in the semiconductor device shown in FIG. 3.

The resistive element 110 is similar to the resistive element 100 of the first embodiment in point of including the resistive conductive layer 24. However, the resistive element 110 comprises a structure different from that of the resistive element 100 of the first embodiment in that a protective layer 46 is provided on the upper surface of the resistive conductive layer 24 in the resistive element 110 while the protective layer 26 (see FIG. 1) is formed so as to cover the resistive conductive layer 24 in the resistive element 100. The following explains the aspects of the semiconductor device of this embodiment different from those of the semiconductor device of the first embodiment.

The resistive element 110 comprises the resistive conductive layer 24 and a planar shape similar to that of the resistive conductive layer 24 of the first embodiment (see FIG. 2). The protective layer 46 is formed on the upper surface of the resistive conductive layer 24, and a third insulating layer 23 is formed on a side surface of the resistive conductive layer 24. The protective layer 46 comprises, for example, a silicon nitride layer or a silicon oxynitride layer. The third insulating layer 23 is formed by oxidizing the surface of the resistive conductive layer 24 comprising, for example, polysilicon. In that case, the third insulating layer 23 comprises a silicon oxide layer.

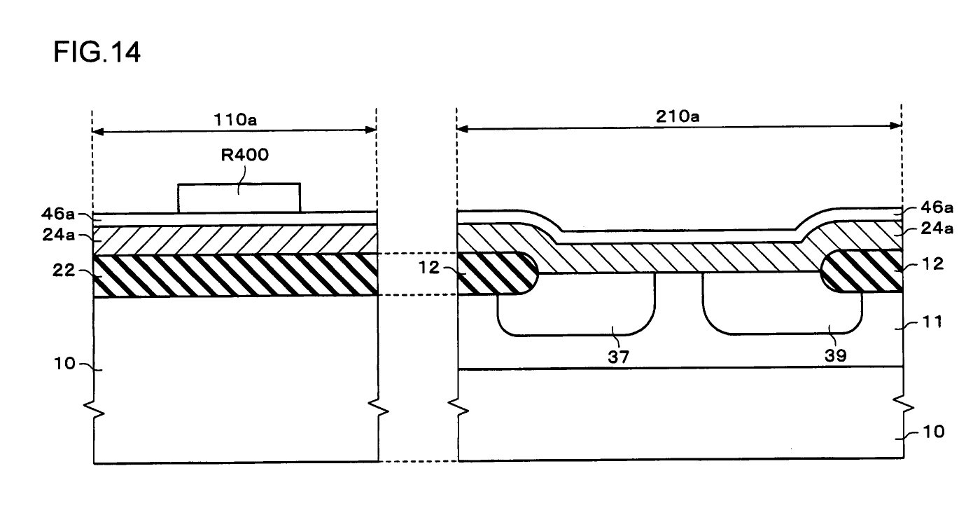

Next, the method of manufacturing the semiconductor device according to this embodiment will be explained with reference to FIG. 13 to FIG. 18. The sectional views of FIG. 14 through FIG. 18 correspond to the section of the semiconductor device shown in FIG. 13. In this embodiment as with the first embodiment, a method of manufacturing the resistive element 110 and the high breakdown voltage MOS transistor 200 of the semiconductor device shown in FIG. 3 will mainly be explained, and explanation for the other parts will be omitted. Hereafter, a region where the resistive element 110 is formed is referred to as ‘a formation region for a resistive element 110a’ while a region where the high breakdown voltage transistor 200 is formed is referred to as ‘the formation region for an MOS transistor 200a.’ In addition, in the following manufacturing process, the aspects different from the semiconductor manufacturing process of the first embodiment are mainly explained.

(A) First, of the manufacturing process of the semiconductor device according to the aforementioned first embodiment, the steps (A) and (B) are conducted. Consequently, the first insulating layer 22 and the elements isolation region 12 are formed on the semiconductor substrate 10 (see FIG. 4 and FIG. 14), and also the wells 11 and 51 (see FIG. 3) as well as the offset regions 37 and 39 (see FIG. 3 and FIG. 14) are formed on the semiconductor substrate 10.

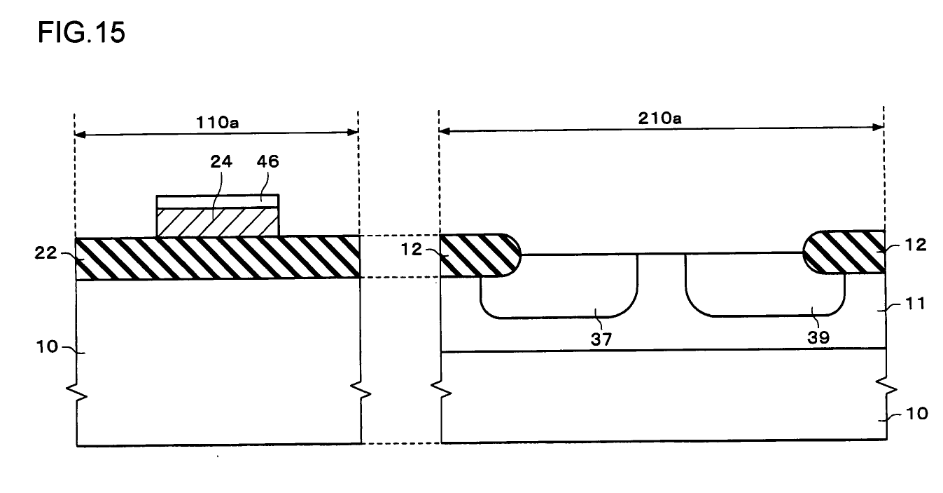

(B) Subsequently, the resistive element 110 is formed in the formation region for a resistive element 110a (see FIG. 15).

More specifically, first, the conductive layer 24a for forming the resistive conductive layer 24 is deposited over the entire surface as shown in FIG. 14. Subsequently, a protective layer 46a is formed on the conductive layer 24a. Then, a resist layer R400 is formed in the formation region for a resistive element 110a. This resist layer R400 is formed in a region on which to form the resistive conductive layer 24. Next, using this resist layer R400 as a mask, the protective layer 46a and the conductive layer 24a are etched, thereby forming the resistive conductive layer 24 in the formation region for a resistive element 110a as shown in FIG. 15. This resistive conductive layer 24 is formed into a planar shape similar to that of the resistive conductive layer 24 of the first embodiment (see FIG. 2). Throughout all the above steps, the resistive element 110 is formed (see FIG. 15). On this resistive element 110, the contacts 90 and 92 are formed in a latter step similarly to the resistive element 100 of the first embodiment (see FIG. 2). Moreover, in this step, the protective layer 46 is formed on the resistive conductive layer 24, and the conductive layer 24a and the protective layer 46a formed in the other regions are removed in this step.

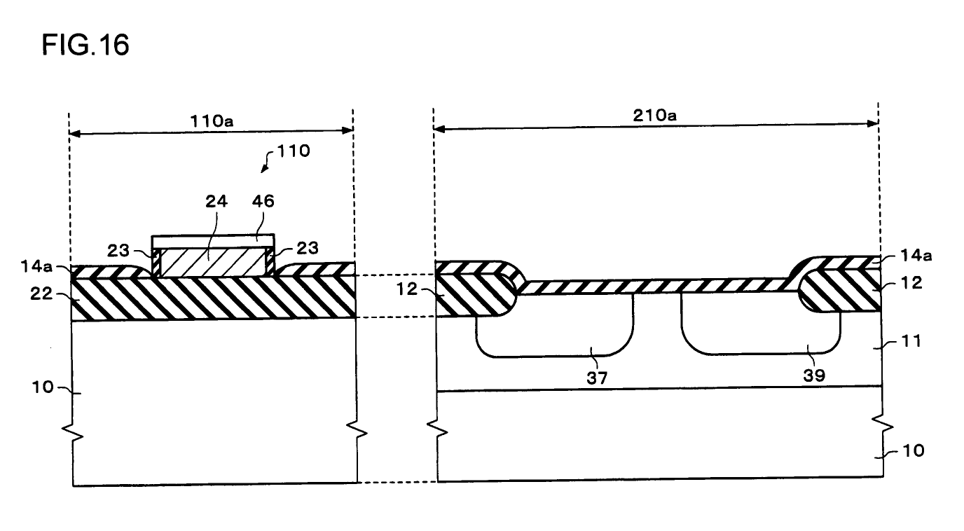

(C) Subsequently, the second insulating layer 14a is formed over the semiconductor substrate 10 in the formation region for a MOS transistor 200a (see FIG. 16).

More concretely, the second insulating layer 14a comprising silicon oxide is formed over the entire surface of the semiconductor substrate 10 by thermal oxidization. Here, this step oxidizes side surfaces of the resistive conductive layer 24 exposed to outside, thereby forming the third insulating layers 23 as shown in FIG. 16.

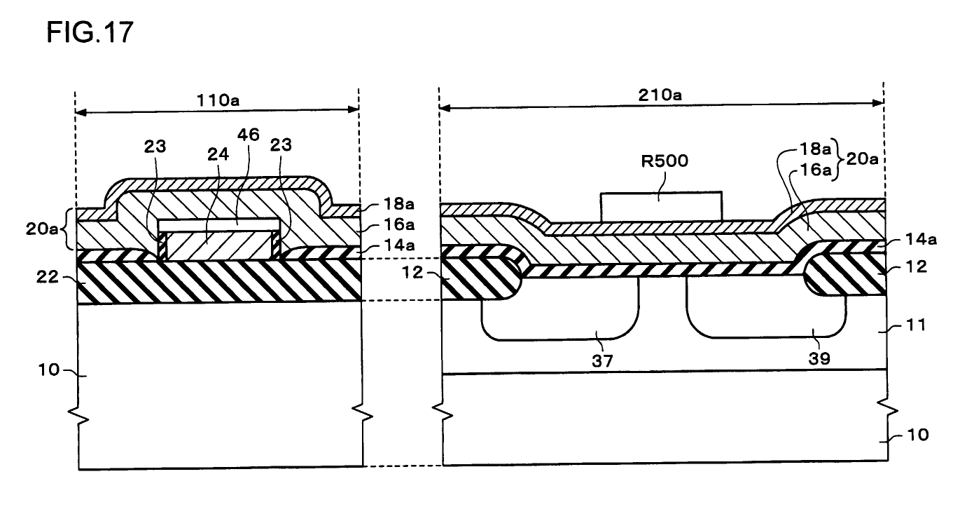

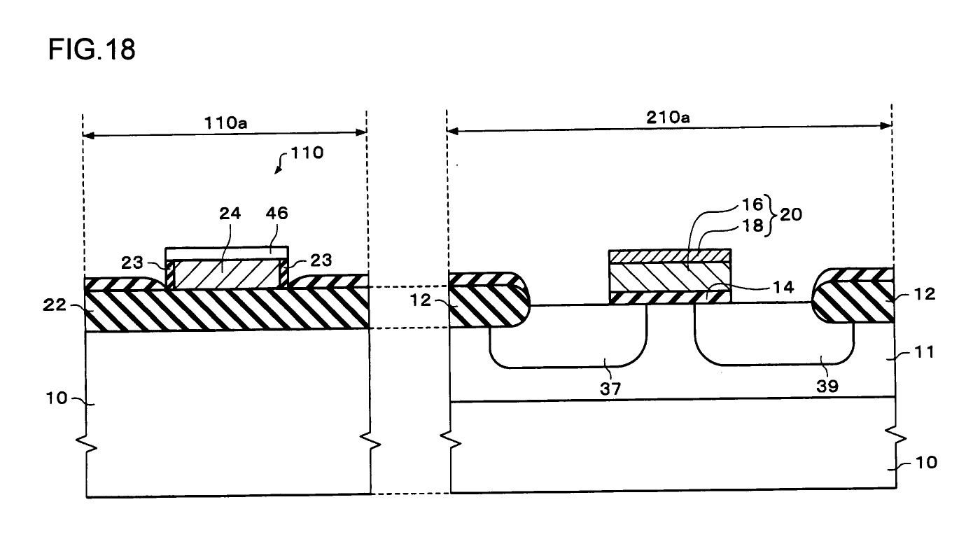

(D) Next, the gate conductive layer 20a for forming the gate electrode 20 is formed over the entire surface (see FIG. 17). Then, using a resist layer R500 as a mask, the second insulating layer 14a and the gate conductive layer 20a in the formation region for an MOS transistor 200a are etched, thereby forming the gate insulating layer 14 and the gate electrode 20 (see FIG. 18).

In the above step, since the manufacturing method and the layer structure of the gate conductive layer 20a, the gate insulating layer 14 and the gate electrode 20 are the same as that of the gate conductive layer 20a of the first embodiment, detailed explanation thereof is omitted.

(E) Subsequently, after forming the side-wall insulating layers 15 on the both side surfaces of the gate electrode 20, the offset regions 37 and 39 are formed in the source and drain regions 17 and 19, respectively (see FIG. 13). The remaining step is the same as the step (H) of the manufacturing method of the semiconductor device of the first embodiment, and detailed explanation thereof is omitted. Throughout all the above steps, the MOS transistor 200 is formed (see FIG. 13).

The semiconductor device and the method of manufacturing it according to this embodiment exhibit the following advantages.

First, the second insulating layer 14a for forming the gate insulating layer 14 is formed in step (C) after forming the protective layer 46 on the upper surface of the resistive conductive layer 24 in the step (B). Consequently, the resistive conductive layer 24 comprising a polysilicon layer can be prevented from getting oxidized, and the resistive conductive layer 24 can be formed so as to have a desired resistance value. Since this advantage is recited in the description of the first embodiment, the detailed explanation thereof is omitted.

Secondly, the resistive conductive layer 24, which forms the resistive element 110 and comprises a polysilicon layer, and the polysilicon layer 16, which forms the gate electrode 20 of the MOS transistor 200, are formed in separate steps, so that each layer is formed to have a property suitable for its function. This advantage is recited in the description of the first embodiment, and thus detailed explanation thereof is omitted.

Thirdly, after the gate conductive layer 20a including the polysilicon layer 16a is formed in step (D) subsequent to forming the protective layer 46 on the upper surface of the resistive conductive layer 24 comprising polysilicon in step (B), the polysilicon layer 16a is etched. In this case, the protective layer 46 functions as a stopper layer. In other words, the protective layer 46 can prevent the top surface of the resistive conductive layer 24 comprising polysilicon from getting etched when the polysilicon layer 16a is etched.

Furthermore, in this embodiment, in step (C), the second insulating layer 14a is formed by thermal oxidization while the third insulating layer 23 is formed on the side surface of the resistive conductive layer 24. Similarly to the protective layer 46, the third insulating layer 23 functions as a stopper layer too in the step of etching the polysilicon layer 16a. In other words, the protective layer 23 can prevent the side surfaces of the resistive conductive layer 24 comprising polysilicon from getting etched when the polysilicon layer 16a is etched in the step (D).

Moreover, in that case, the second insulating layer 14a for forming the gate insulating layer 14 of the MOS transistor 200 is formed by thermal oxidization process in step (D), and the stopper layer (the third insulating layer 23) of the resistive conductive layer 24 of which function is used in etching for forming the gate electrode 20 of the MOS transistor 200 is formed. Since it is possible to form the second insulating layer 14a for the gate insulating layer 14 and the stopper layer (the third insulating layer 23) of the resistive conductive layer 24 in the same step by the thermal oxidization process, the manufacturing process can be simplified.

Fourth, before forming the gate insulating layer 14 and the gate electrode 20 of the MOS transistor 200, the resistive element 110 is formed. Consequently, the resistive element 110 can be formed without being restricted by the manufacturing process to be used in forming the gate-insulating layer 14 and the gate electrode 20 of the MOS transistor 200.

Fifthly, using the resist layer R400, the conductive layer 24a and the protective layer 46a are etched at once in step (B). Accordingly, the number of manufacturing steps can be reduced in comparison with the manufacturing method of the semiconductor device of the first embodiment, thereby improving the manufacturing process.

The present invention is not limited to the above embodiments and can be modified in various manners. For example, the present invention covers substantially the same configurations as those of the described embodiments (for example, a configuration with the same function, method and result or a configuration with the same purpose and result). Moreover, the present invention includes a configuration in which nonessential parts of the configurations explained in the embodiments are replaced. Furthermore, the invention comprises a configuration that exhibits the same advantage as those of the configurations explained in the embodiments or a configuration with which the same goal can be achieved. Also, the invention comprises a configuration in which additional technology is added to the configurations explained in the embodiments.

For example, the above embodiment illustrates a case that a n-type impurity is doped so as to form the resistive conductive layer 24; however, the resistive element can be formed from p-type impurity.

Moreover, for example, the above embodiments describe that the MOS transistor 200 is an n-type MOS, namely, that the semiconductor substrate 10 is a p-type silicon substrate, the impurity doped into the source and drain regions 17 and 19 of the transistor 200 is n-type impurity, and impurity doped into the well 11 and the gate electrode 20 of the semiconductor substrate 10 is p-type impurity. However, switching the type into the other for each layer does not depart from the spirit of the invention. Thus, even when the transistor 200 is a p-type MOS, the same advantage and effect can be exhibited.

Furthermore, for example, the bulk semiconductor substrate is used as the semiconductor layer in the embodiments; however, an SOI substrate can be used for the semiconductor layer.

What is claimed is:

1. A method of manufacturing a semiconductor device in which a resistive conductive layer and a MOS transistor are provided on a same semiconductor layer, the method comprising:
forming a first insulating layer over the semiconductor layer in a formation region for the resistive conductive layer;
forming an elements isolation region in a formation region for the MOS transistor;
forming the resistive conductive layer on the first insulating layer in the formation region for the resistive conductive layer;
forming a protective layer so as to cover the resistive conductive layer in the formation region for the resistive conductive layer;
forming a second insulating layer on the semiconductor layer by exposing a surface of the semiconductor layer and thermally oxidizing the surface of the semiconductor layer in the formation region for the MOS transistor;
forming a gate conductive layer at least on the second insulating layer; and
forming a gate electrode and a gate insulating layer by patterning the gate conductive layer and the second insulating layer in the formation region for the MOS transistor.

2. A method of manufacturing a semiconductor device in which a resistive conductive layer and an MOS transistor are provided on a same semiconductor layer, the method comprising:
forming a first insulating layer over the semiconductor layer in a formation region for the resistive conductive layer;
forming an elements isolation region in a formation region for the MOS transistor;
forming the resistive conductive layer on the first insulating layer in the formation region for the resistive conductive layer;
forming a protective layer on the resistive conductive layer in the formation region for the resistive conductive layer;
forming a second insulating layer on the semiconductor layer by exposing a surface of the semiconductor layer and thermally oxidizing the surface of the semiconductor layer in the formation region for the MOS transistor;
forming a third insulating layer on a side surface of the resistive conductive layer;
forming a gate conductive layer at least on the second insulating layer; and
forming a gate electrode and a gate insulating layer by patterning the gate conductive layer and the second insulating layer in the formation region for the MOS transistor.

3. The method of manufacturing a semiconductor device according to claim 1 or claim 2, wherein the gate conductive layer comprises a multi-layered structure including a polysilicon layer and a metal layer.

4. The method of manufacturing a semiconductor device according to any one of claims 1 or 2, wherein the resistive conductive layer comprises a polysilicon layer.

5. The method of manufacturing a semiconductor device according to any one of claims 1 or 2, wherein the first insulating layer and the elements isolation region are formed in a same step.

6. The method of manufacturing a semiconductor device according to claim 5, wherein the first insulating layer and the elements isolation region are formed by oxidizing the surface of the semiconductor layer.

7. The method of manufacturing a semiconductor device according to any one of claims 1 or 2 wherein the resistive conductive layer, and a high breakdown voltage transistor and a low breakdown voltage transistor of an insulated gate type are formed on the same semiconductor layer, the high breakdown voltage transistor including a proof voltage between a source and a drain of the high breakdown voltage transistor, which is different from that of the low breakdown voltage transistor, and the MOS transistor comprises the high breakdown voltage transistor.

8. The method of manufacturing a semiconductor device according to any one of claims 1 or 2 wherein the second insulating layer is formed by exposing at least a region of the semiconductor layer on which to form the gate electrode and then thermally oxidizing the surface thereof in the formation region for the MOS transistor.

9. The method of manufacturing a semiconductor device according to claim 1, wherein the semiconductor layer comprises a layer including a silicon substrate on the surface thereof, wherein the first and the second insulating layers each comprise a silicon oxide layer, and wherein the protective layer comprises a silicon nitride layer or a silicon oxynitride layer.

10. The method of manufacturing a semiconductor device according to claim 2, wherein the semiconductor layer comprises a layer including a silicon layer at least on the surface thereof, the first, the second and the third insulating layers each comprise a silicon oxide layer, and the protective layer comprises a silicon nitride layer or a silicon oxynitride layer.

11. The method of manufacturing a semiconductor device according to claim 2, wherein the second insulating layer and the third insulating layer are formed in a same step.

12. The method of manufacturing a semiconductor device according to claim 11, wherein each of the second insulating layer and the third insulating layer is formed by oxidizing the surface of the semiconductor layer and the side surface of the resistive conductive layer.

13. A semiconductor device, comprising:
a semiconductor layer;
an MOS transistor formed on the semiconductor layer; and
a resistive conductive layer formed on the semiconductor layer through an insulating layer, wherein;
the MOS transistor comprises a gate insulating layer and a gate electrode formed on the gate insulating layer.

14. The semiconductor device according to claim 13, wherein the gate electrode comprises a multi-layered structure including a polysilicon layer and a metal layer.

15. The semiconductor device according to claim 13 or claim 14, wherein the resistive conductive layer comprises a polysilicon layer.

16. The semiconductor device according to any one of claims 13 or 14, wherein the semiconductor layer comprises a layer including a silicon layer at least on the surface thereof, and the gate-insulating layer comprises a silicon oxide layer.

17. The semiconductor device according to any one of claims 13 or 14, wherein a high breakdown voltage transistor and a low breakdown voltage transistor of insulated gate types are formed on the semiconductor layer, the high breakdown voltage transistor including a proof voltage between a source and a drain which is different from that of the low breakdown voltage transistor, and wherein the MOS transistor comprises the high breakdown voltage transistor.

18. The semiconductor device according to any one of claims 13 or 14, further comprising a protective layer formed so as to cover the resistive conductive layer.

19. The semiconductor device according to any one of claims 13 or 14, further comprising a protective layer formed on the resistive conductive layer.

20. The method of manufacturing a semiconductor device according to claim 1, wherein the step of forming the resistive conductive layer and the gate electrode are done separately.

21. The method of manufacturing a semiconductor device according to claim 2, wherein the step of forming the resistive conductive layer and the gate electrode are done separately.

22. The method of manufacturing a semiconductor device according to claim 2, wherein said step of forming the second insulating layer and the step of forming the third insulating layer are formed in a same step.

23. The method of manufacturing a semiconductor device according to claims 1 and 2, wherein the resistive conductive layer is doped with an impurity to create a predetermined resistance.

24. The semiconductor device according to claim 14, wherein said metal layer comprises a metal selected from the following group: tungsten and molybdenum.

25. The method of manufacturing a semiconductor device according to claim 8, wherein said exposing step and said oxidizing step are performed when said protective layer covers said resistive conductive layer.

26. The method of manufacturing a semiconductor device according to claim 3, wherein the resistive conductive layer comprises a polysilicon layer.

27. The method of manufacturing a semiconductor device according to claim 3, wherein the first insulating layer and the elements isolation region are formed in a same step.

28. The method of manufacturing a semiconductor device according to claim 4, wherein the first insulating layer and the elements isolation region are formed in a same step.

29. The semiconductor device according to claim 15, wherein the semiconductor layer comprises a layer including a silicon layer at least on the surface thereof, and the gate-insulating layer comprises a silicon oxide layer.

30. The semiconductor device according to claim 15, wherein a high breakdown voltage transistor and a low breakdown voltage transistor of insulated gate types are formed on the semiconductor layer, the high breakdown voltage transistor including a proof voltage between a source and a drain which is different from that of the low breakdown voltage transistor, and wherein the MOS transistor comprises the high breakdown voltage transistor.

31. The semiconductor device according to claim 16, wherein a high breakdown voltage transistor and a low breakdown voltage transistor of insulated gate types are formed on the semiconductor layer, the high breakdown voltage transistor including a proof voltage between a source and a drain which is different from that of the low breakdown voltage transistor, and wherein the MOS transistor comprises the high breakdown voltage transistor.

32. The method of manufacturing a semiconductor device according to claim 4, wherein the MOS transistor comprises a twin-well structure.

33. The method of manufacturing a semiconductor device according to claim 4, wherein the MOS transistor comprises a triple-well structure.
